(19) United States
(12) Patent Application Publication
(10) Pub. No.: US 2005/0219829 A1
(43) Pub. Date: Oct. 6, 2005

(54) Printed circuit board and electronic apparatus using the same

(75) Inventor: Kuo-Chun Lee, Taoyuan (TW)

Correspondence Address: BIRCH STEWART KOLASCH & BIRCH, PO BOX 747, FALLS CHURCH, VA, 22040-0747, US

(73) Assignee: BENQ CORPORATION

(21) Appl. No.: 11/094,284

(22) Filed: Mar. 31, 2005

(30) Foreign Application Priority Data
Apr. 2, 2004 (TW) 93109211

(51) Int. Cl. H05K 1/03

(52) U.S. Cl. 361/761; 174/262; 257/774; 361/762

(57) ABSTRACT

A printed circuit board and an electronic apparatus utilizing the same. The electronic apparatus includes the printed circuit board and a dual-inline-package (DIP) device. The printed circuit board includes a pair of holes. The pair of holes has a geometrical center, and is substantially symmetrical with respect to the geometric center so that each hole is arc-shaped. The DIP device includes a pair of pins, and is disposed on the printed circuit board by inserting the pins into the holes.

### BACKGROUND

The invention relates to an electronic apparatus and a printed circuit board thereof, and in particular, to a printed circuit board with DIP (dual inline package) devices.

Typically, DIP devices are disposed on the printed circuit boards of electronic apparatuses by an auto insert (AI) method. Referring to FIGS. 1a and 1b, the DIP devices 1 are disposed on a fixture 2 during assembly. After pins 1a of the DIP device 1 are aligned with holes 3a of the printed circuit board 3, the fixture 2 moves downward to insert the pins 1a into the holes 3a. Thus, the DIP devices 1 are installed on the printed circuit board 3.

Since the holes 3a are circular, the pins 1a of the DIP device 1 may not be inserted into the holes 3a due to small deviation in position or orientation. Thus, the yield of assembly is difficult to enhance.

### SUMMARY

An embodiment of the invention provides a printed circuit board comprising a pair of holes. The pair of holes has a geometrical center, and is substantially symmetrical with respect to the geometric center so that each hole is arc-shaped.

Furthermore, each hole extends a first dimension along a first direction in a plane where the pair of holes is formed, and the first dimension is larger than any dimension in the plane of each hole.

Moreover, a center line is defined on the printed circuit board, and the pair of holes is symmetrical with respect to the center line.

Additionally, a central angle formed by each hole is less than 180 degrees.

An electronic apparatus is also provided, comprising a printed circuit board and a dual-inline-package (DIP) device. The printed circuit board is formed with a pair of holes. The pair of holes has a geometrical center, and is substantially symmetrical with respect to the geometric center so that each hole is arc-shaped. The DIP device comprises a pair of pins, and is disposed on the printed circuit board by inserting the pins into the holes.

### BRIEF DESCRIPTION OF THE DRAWINGS

The invention can be more fully understood by reading the subsequent detailed description and examples with references made to the accompanying drawings, wherein:

FIG. 1a is a schematic view of DIP devices disposed on a conventional printed circuit board;

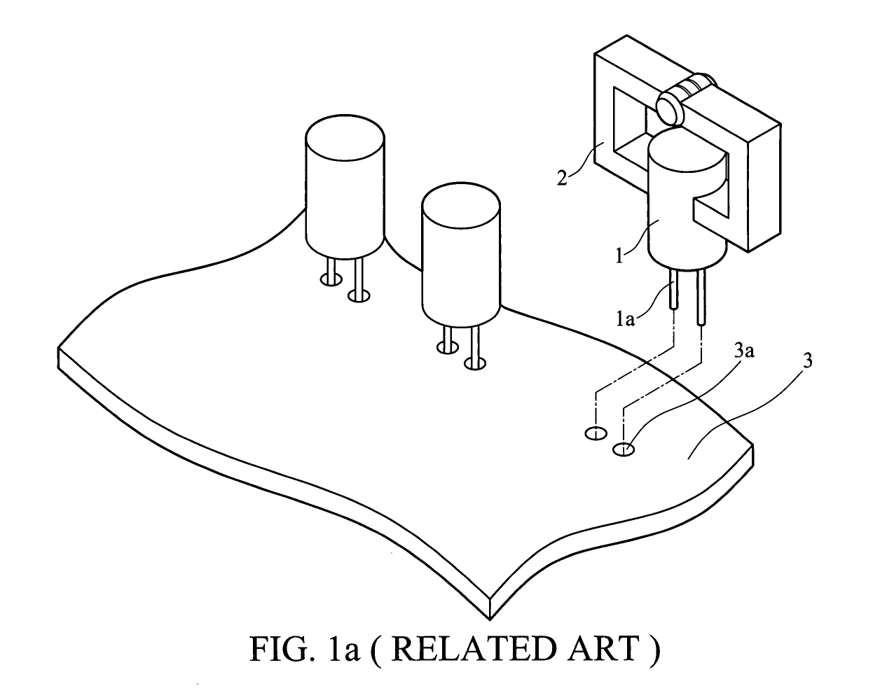

FIG. 1b is a partial enlarged view of the printed circuit board in FIG. 1a;

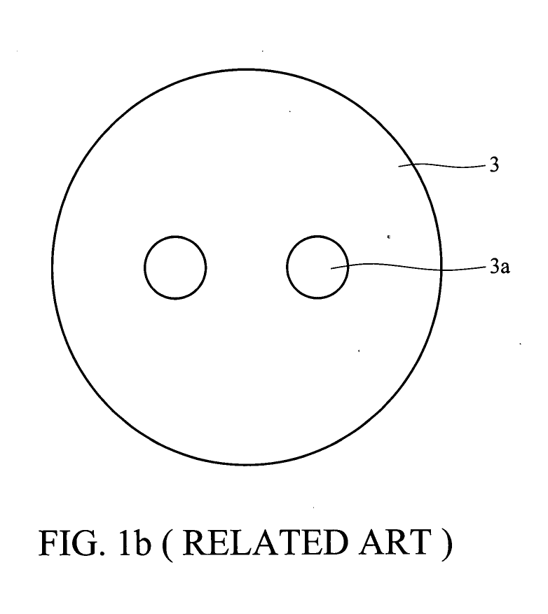

FIG. 2a is a schematic view of an embodiment of an electronic apparatus;

FIG. 2b is a partial enlarged view of a printed circuit board in FIG. 2a;

FIG. 3a is a schematic view of an embodiment of an electronic apparatus;

FIG. 3b is a partial enlarged view of a printed circuit board in FIG. 3a.

### DETAILED DESCRIPTION

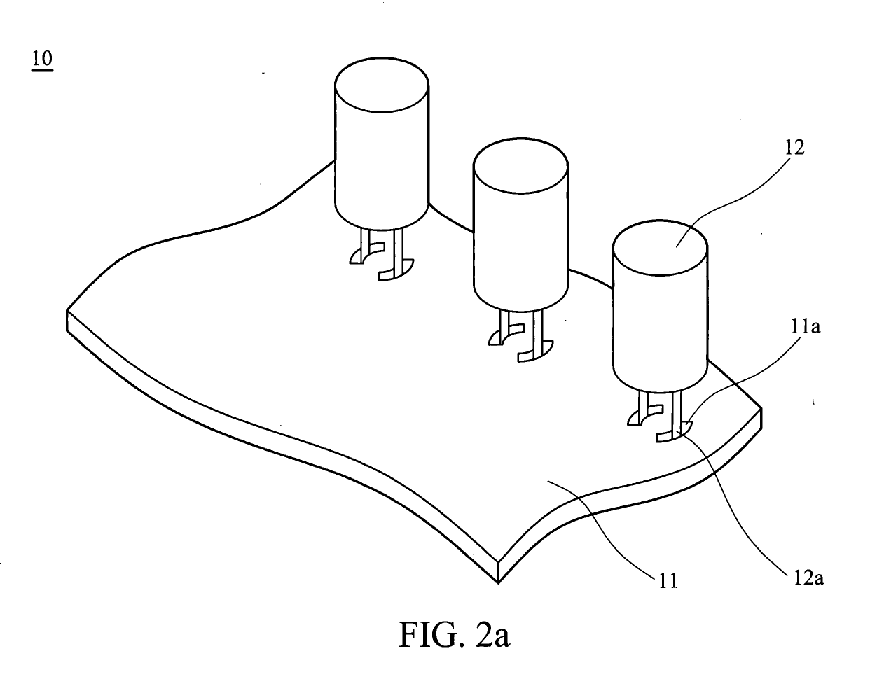

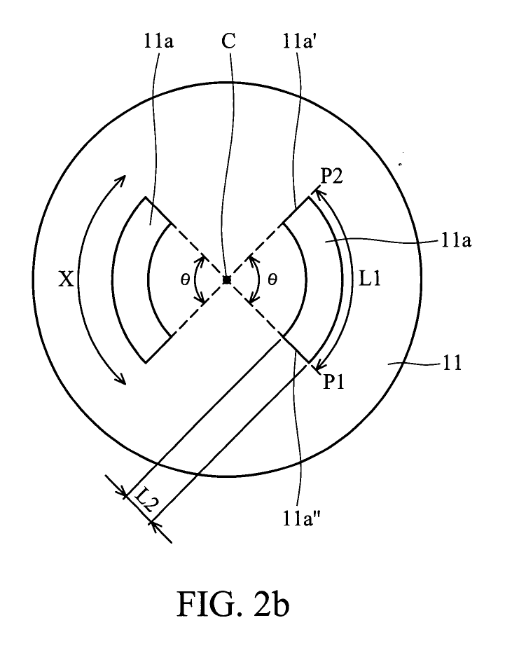

FIGS. 2a and 2b are schematic views of an embodiment of an electronic apparatus 10. The electronic apparatus 10 comprises a printed circuit board 11 and three DIP devices 12. Although only three DIP devices 12 are shown in FIG. 2a, it is not limited thereto. In practice, more than three DIP devices can be disposed on the printed circuit board.

The printed circuit board 11 comprises three pairs of holes 11a. Each pair of holes 11a has a geometric center C as shown in FIG. 2b, and is symmetrical with respect to the geometric center C. Each hole 11a is arc-shaped, and has a first end 11a′ and a second end 11a″. A first axis P1 connects the geometric center C and the first end 11a′, and a second axis P2 connects the geometric center C and the second end 11a″. A central angle θ formed by each hole 11a, intersected by the first axis P1 and the second axis P2, is less than 180 degrees.

Each hole 11a substantially extends in a first direction X in the plane where the pair of holes exist by a first dimension L1. The first dimension L1 exceeds a second dimension, such as L2, extending in a second direction of the hole 11a.

Referring to FIG. 2a, each DIP device 12 comprises a pair of pins 12a, and is disposed on the printed circuit board 11 by inserting the pins 12a into the holes 11a.

As stated above, since the holes 11a of the embodiment are not circular, the margin for inserting the DIP device increases. Even if the pins are slightly deviated, they can be smoothly inserted into the holes, thus enhancing the yield.

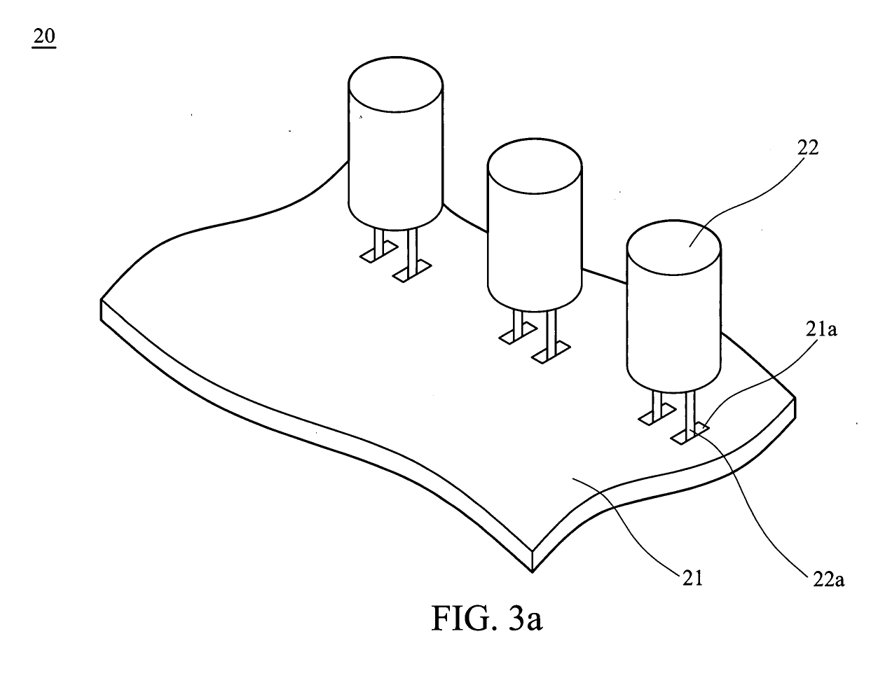

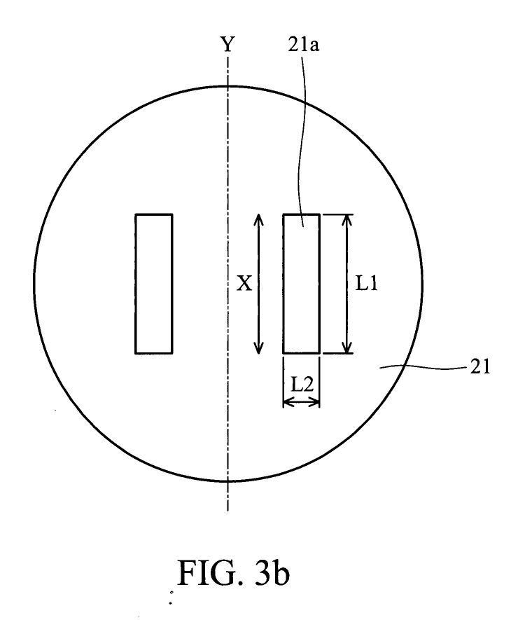

FIGS. 3a and 3b are schematic views of an embodiment of an electronic apparatus 20. The electronic apparatus 20 comprises a printed circuit board 21 and three DIP devices 22.

Holes 21a of the printed circuit board 21 are substantially rectangular. As shown in FIG. 3b, a center line Y is located between each pair of holes 21a. Each pair of holes 21a is symmetrical with respect to the center line Y.

Each hole 21a substantially extends in a first direction X parallel with the center line Y by a first dimension L1. The first dimension L1 exceeds a second dimension, such as L2, extending in a second direction of the hole 21a.

As stated above, since the holes 21a of the embodiment are rectangular, the margin for inserting the DIP device increases. Even if the pins are slightly deviated, they can be smoothly inserted into the holes, thus enhancing the yield.

While the invention has been described by way of example and in terms of preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A printed circuit board comprising a pair of holes which has a geometrical center and is substantially symmetrical with respect to the geometric center so that each hole is arc-shaped.

2. The printed circuit board as claimed in claim 1, wherein each hole extends a first dimension along a first direction in a plane where the pair of holes is formed, and the first dimension is larger than any dimension in the plane of each hole.

3. The printed circuit board as claimed in claim 1, wherein a center line is defined on the printed circuit board, and the pair of holes is symmetrical with respect to the center line.

4. The printed circuit board as claimed in claim 1, wherein a central angle formed by each hole is less than 180 degrees.

5. An electronic apparatus comprising:
a printed circuit board including a pair of holes which has a geometrical center and is substantially symmetrical with respect to the geometric center so that each hole is arc-shaped; and
a DIP device including a pair of pins, disposed on the printed circuit board by inserting the pins into the holes.

6. The electronic apparatus as claimed in claim 5, wherein each hole extends a first dimension along a first direction in a plane where the pair of holes is formed, and the first dimension is larger than any dimension in the plane of each hole.

7. The electronic apparatus as claimed in claim 5, wherein a center line is defined on the printed circuit board, and the pair of holes is symmetrical with respect to the center line.

8. The electronic apparatus as claimed in claim 5, wherein a central angle formed by each hole is less than 180 degrees.
